(19) United States
(12) Patent Application Publication
(10) Pub. No.: US 2011/0127222 A1
(43) Pub. Date: Jun. 2, 2011

(54) TRAPPING MAGNETIC CELL SORTING SYSTEM

(75) Inventors: David A. Chang-Yen, Oxnard, CA (US); Jafar Darabi, Goleta, CA (US); Yanting Zhang, Santa Barbara, CA (US); Paul Pagano, Moorpark, CA (US)

(73) Assignee: CYNVENIO BIOSYSTEMS, INC., Westlake, CA (US)

(21) Appl. No.: 12/933,395

(22) PCT Filed: Mar. 19, 2009
(86) PCT No.: PCT/US09/37714

§ 371 Date: Jan. 27, 2011

Related U.S. Application Data
(60) Provisional application No. 61/037,994, filed on Mar. 19, 2008.

(51) Int. Cl. B01D 35/06; B03C 1/30; B81B 7/00

(52) U.S. Cl. 210/695; 210/222; 210/205; 210/85

(57) ABSTRACT

A system for sorting and trapping magnetic target species includes a microfluidic trapping chamber designed to receive and then temporarily hold magnetic particles in place within the module. An external magnetic source moves relatives to the fluid chamber as the magnetic particles flow the device in the fluidic medium. The magnetic particles flowing into the module are trapped there while the other sample components (non-magnetic) continuously flow through and out of the station, thereby separating and concentrating the species captured on the magnetic particles. The magnetic particles and/or their payloads may be released and separately collected at an outlet after the sample passes through the trapping module.

### CROSS-REFERENCE TO RELATED APPLICATIONS

This application claims priority under U.S.C. §119 to provisional application 61/037,994, titled “TRAPPING MAGNETIC CELL SORTING SYSTEM,” filed on Mar. 19, 2008, the disclosure of which is incorporated herein in its entirety for all purposes.

### FIELD OF INVENTION

This invention pertains generally to biological cell sorting. More specifically, this invention pertains to the design and mechanism of a trapping magnetic cell sorting system.

### BACKGROUND

Sorting cells based on their surface markers is an important capability in biology and medicine. Magnetic Activated Cell Sorting (MACS) is sometimes used as a cell sorting technique because it allows the rapid selection of a large number of target cells. The applications of MACS span a broad spectrum, ranging from protein purification to cell based therapies. Typically, target cells are labeled with one or more superparamagnetic particles that are conjugated to a molecular recognition element (e.g. a monoclonal antibody) which recognizes a particular cell surface marker.

Application of MACS has frequently been limited to pre-enrichment before fluorescence-based cytometry. Nevertheless, due to its high throughput compared to other methods such as Fluorescence Activated Cell Sorting (FACS), MACS is still a competitive technology.

In order to achieve high throughput and high recovery of the rare cells (or other target components), improvements on existing MACS systems are needed.

### SUMMARY

A disclosed system for sorting and trapping magnetic target species includes a microfluidic trapping chamber designed to receive and then temporarily hold magnetic particles in place within the module. An external magnetic source moves relatives to the fluid chamber as the magnetic particles flow the device in the fluidic medium. The magnetic particles flowing into the module are trapped there while the other sample components (non-magnetic) continuously flow through and out of the station, thereby separating and concentrating the species captured on the magnetic particles. The magnetic particles and/or their payloads may be released and separately collected at an outlet after the sample passes through the trapping module.

In one aspect, the present invention pertains to a fluidic sorting device having a chamber with at least one inlet and one outlet, and a surface for retaining magnetic particles. The fluidic sorting device also includes an external magnetic source and means for moving the magnetic source relative to the chamber. The moving means may be an actuator, for example, a cam actuator. The external magnetic source may be one or many permanent magnets or electromagnets. The chamber surface for retaining the particles may include a magnetic field gradient generator, which may be a ferromagnetic structure in a random pattern or an organized pattern, e.g., lines, grids, arrays, or geometric shapes. Other stations may be included on the sorting device, such as a pre-processing station or a post-processing station.

Various aspects of the invention may be characterized as a progressive application of a magnetic field to a trapping station to oppose the fluid flow within said trapping station to thereby cease movement as the trapping region is gradually addressed by said magnetic field. In other words, the magnetic field is shifted so as to produce a time varying magnetic field in the trapping region, thereby inducing a desired magnetic particle motion. The magnetic field may move continuously during magnetic particle flow. The field may move from a downstream position toward an upstream position, or vice versa. The movement may serve to spread the magnetic bead bound target particles over the trapping region in a uniform manner. This may facilitate, inter alia, post-separation operations, such as bead release by allowing a release reagent to efficiently access magnetic bead-bound target species.

These and other features and embodiments of the invention will be described in more detail below with reference to the associated drawings.

### BRIEF DESCRIPTION OF THE DRAWINGS

FIG. 1A shows a system that employs disposable fluidics chips or cartridges.

FIGS. 1B and 1C illustrate a magnetic trapping module in accordance with certain embodiments.

FIG. 2A depicts an embodiment in which a magnetic field producer (e.g., a permanent magnet) moves over one surface of the trapping region during the passage of magnetic particles through the trapping region.

FIGS. 2B-2E present an example of a cam system is used to move a plurality of magnets into position to apply a magnetic field to a fluidics trapping region.

FIG. 2F presents an example of a staged capture and release trapping system.

FIG. 3A depicts a fluidics input for a sample well and a bead release reagent well.

FIG. 3B shows a structure of a magnetic trap disposed in a fluidics device for post-capture treatment of target species.

FIGS. 4A-4H depict examples of different types of ferromagnetic MFG structures that may be employed with this invention.

FIG. 5 presents examples of non-magnetic capture features fabricated among a soft-magnetic (e.g., nickel) pattern.

FIGS. 6A-6C shows examples of random array of ferromagnetic structures.

### DESCRIPTION OF CERTAIN EMBODIMENTS

### Introduction and Context

Magnetic Activated Cell Sorting (MACS) systems are capable of high-purity selection of the labeled cells or other sample components. In certain embodiments these systems operate in a “trapping mode” where the non-target and target species are sequentially eluted after the application of the external magnetic field. In other words, the species attached to magnetic particles are held in place while the unattached species are eluted. Then, after this first elution step is completed, the species that are attached magnetic field and were prevented from being eluted are freed in some manner such that they can be eluted and recovered.

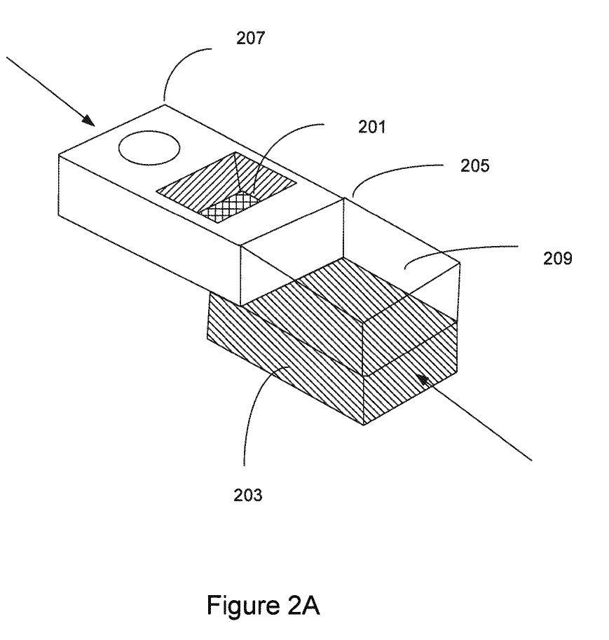

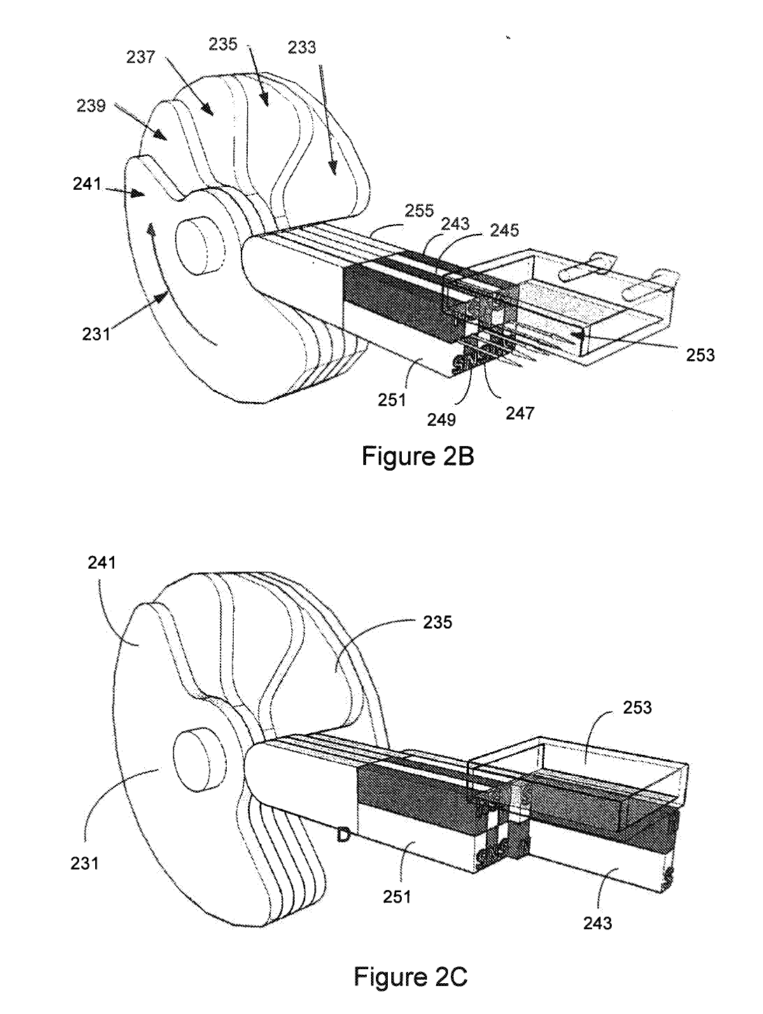

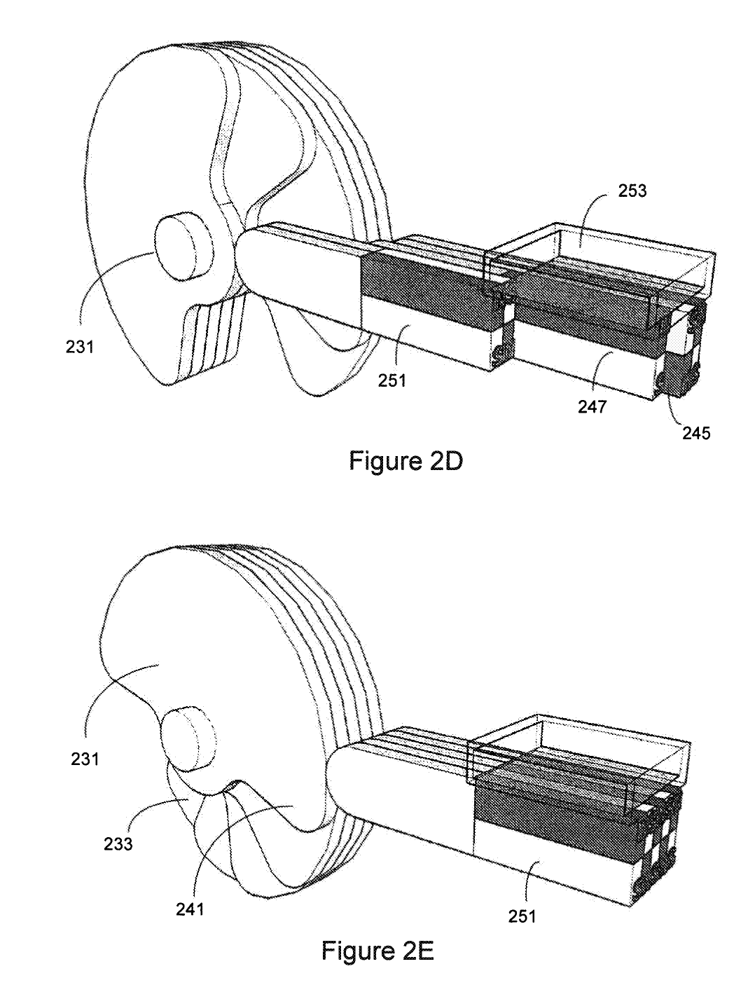

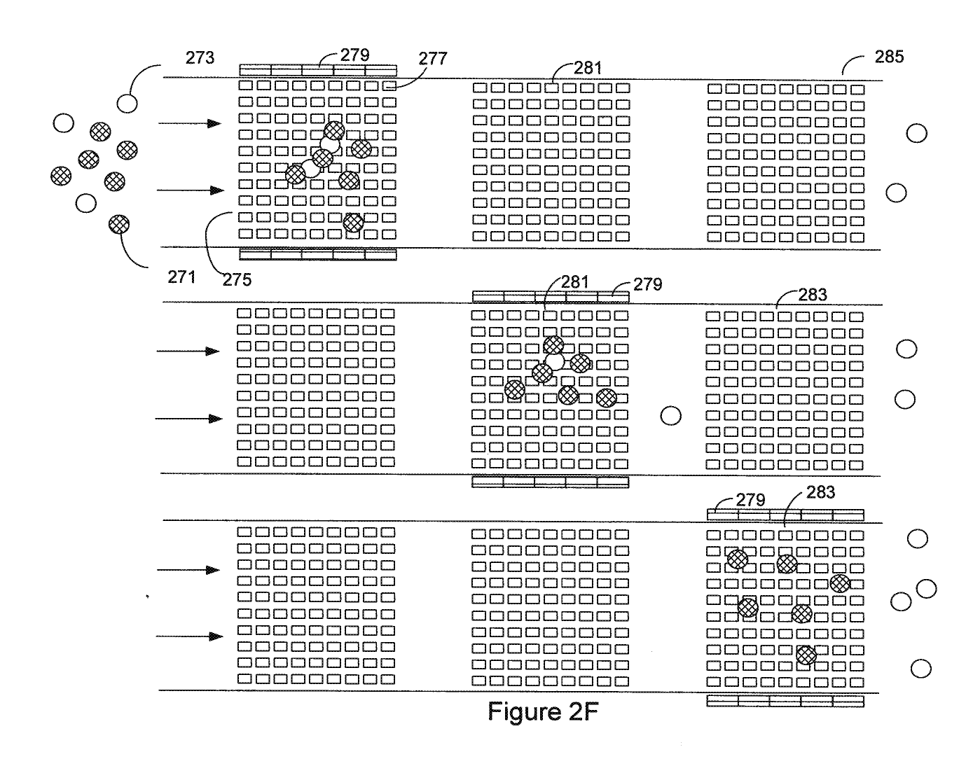

In accordance with embodiments of this invention, a dynamically varying magnetic field is applied to the trapping region during flow and trapping of the magnetic particles. This may involve, for example, progressive insertion of a magnetic field over the trapping region during the trapping operation. As explained below in more detail, this permits certain advantages such as prevention of clumping of magnetic particles at the entry way to the trapping region. Examples of systems that allows for dynamically varying magnetic fields is depicted in FIGS. 2A and 2B-2E which will be described in more detail below.

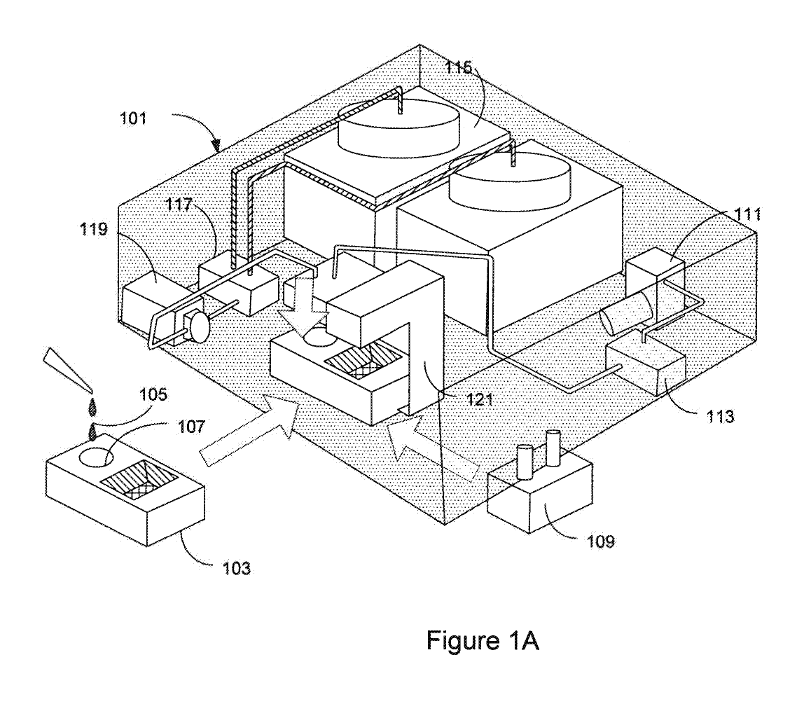

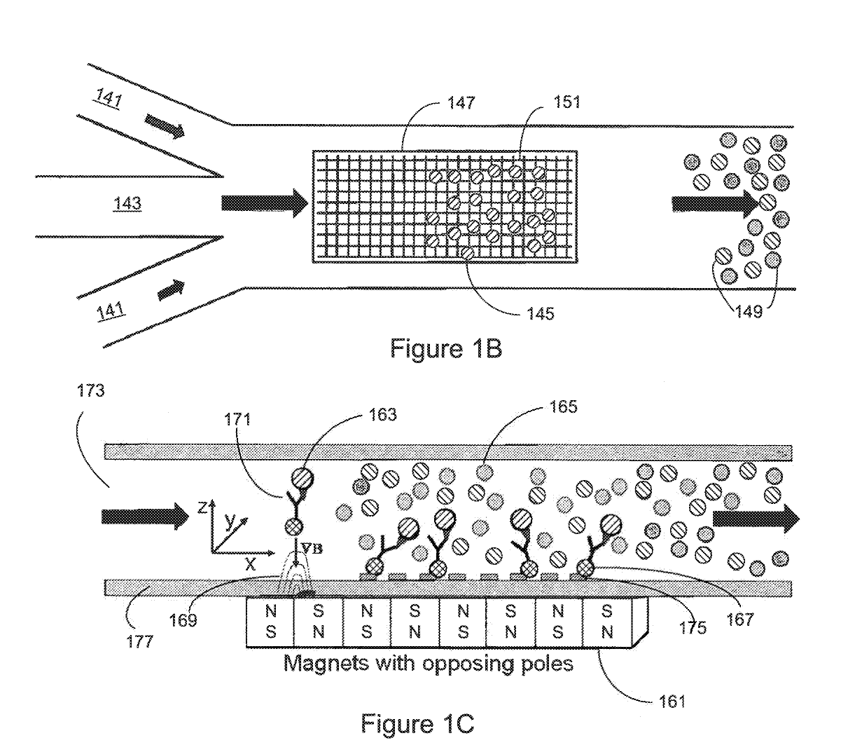

For context an example of a trapping-type magnetic separation system will now be described. FIGS. 1A and 1B illustrate magnetic sorting modules and systems in accordance with certain embodiments. FIG. 1A shows a system that employs disposable fluidics chips or cartridges. Each chip or cartridge houses fluidics elements that include a magnetic trapping module. In one mode of operation (positive selection), a sample such as a small quantity of blood is provided to a receiving port of the cartridge and then the cartridge with sample in tow is inserted into a processing and analysis instrument. Within the chip, the magnetic particles and the target species (if any) from the sample are sorted and concentrated at the magnetic trapping module. After sample has been processed in this manner, trapped species may be released and collected in output tubes. This may be accomplished by various means including reducing or eliminating the external magnetic field applied to the trapping module or applying a reagent that releases captured species from magnetic particles. Alternatively, or in conjunction, the hydrodynamic force exerted on the magnetic particles may be increased. In the depicted embodiment, a pressure system (including a syringe pump and a pressure controller) provides the principal driving force for flowing sample through the trapping module. Of course, other designs may be employed using alternative driving forces such as a continuous pump. Buffer from buffer reservoirs is also provided to the cartridge under the controlled by a buffer pump and a flow control module.

On the right side of FIG. 1A, an example processing sequence is shown. Specifically, the process begins by loading a sample onto the chip or cartridge before inserting into the instrument. Then the chip is inserted into the instrument to align the external magnet(s), fluidics couplings, and associated apparatus. Thereafter, a collection tube or tubes is also loaded into the instrument. Note that in some embodiments the order of loading to the instrument can be varied. Next, a fluidics interface is secured to the chip to ensure leakproof delivery of sample and buffer to the chip. Finally, the instrument commences the separation process.

FIGS. 1B and 1C shows top and side views of a trapping module in accordance with one embodiment. In a specific example, the depicted trapping module is implemented in a disposable cartridge as shown in FIG. 1A. In FIG. 1B, a top view of the magnetic trapping module is shown to include a central sample inlet, and two buffer inlets straddling the sample inlet. Buffer delivered from the buffer inlets may prevent contents of the sample from becoming entrained along the edge of the trapping module, and help to stabilize the pressure as well as the flow streams. As shown, a trapping region, which in this embodiment includes a ferromagnetic pattern is formed on a bottom wall of a flow channel. The channel wall on which the pattern is formed may be transparent, semi-transparent or opaque.

As shown, target species are captured on the trapping region. The remaining uncaptured cells and debris provided with the sample are washed clear of the trapping region because they are not affixed to magnetic particles.

It should be noted that positive or negative trapping schemes may be employed. In a positive trapping scheme as shown in FIG. 1B, target species are linked to the surfaces of the magnetic particles and are thereafter trapped together with the magnetic particle in the trapping region. This effectively purifies and concentrates the target species. In negative trapping embodiments, non target species (rather than target species) are labeled with magnetic particles. Thus, the target species continuously flow through the trapping module, while the labeled non-target species are trapped in the trapping region and removed from suspension. This approach purifies the target species, but does so without concentrating them.

A side view of the trapping region in action is depicted in FIG. 1C. As shown there, ferromagnetic structures are formed on the inside surface of a lower wall of a flow channel. These serve as a magnetic field gradient generating (MFG) structures (described in more detail below). An external magnetic field is typically used as the driving force for trapping the magnetic particles flowing through the fluid medium. The MFG structures may shape the external magnetic field in order create locally high magnetic field gradients to assist capturing flowing magnetic particles. In the depicted embodiment of FIGS. 1B and 1C, the external magnetic field is provided by an array of permanent magnets of alternating polarity. More generally, the external magnetic field may be produced by one or more permanent magnets and/or electromagnets. In some embodiments, a collection of magnets such as those shown in FIG. 1C are moveable, individually or as a unit, in order to dynamically vary the magnetic field applied to the trapping region.

In certain embodiments, the magnetic field is controlled using an electromagnet. In other embodiments, permanent magnets may be used, which are mechanically movable into and out of proximity with the sorting station such that the magnetic field gradient in the sorting region can be locally increased and decreased to facilitate sequential capture and release of the magnetic particles. In some cases using an electromagnet, the magnetic field is controlled so that a strong field gradient is produced early in the process (during capture of the magnetic particles) and then reduced or removed later in the process (during release of the particles).

As shown in the example of FIG. 1C, the magnetic particles are coated with a molecular recognition elements (e.g., antibodies) specific for a marker of a target cell or other species to be captured. Thus, one or more magnetic particles, along with a bound cell or other target species, flow as a combined unit into the trapping module. For large target species having many exposed binding moieties (e.g., mammalian cells), it will be common to have multiple magnetic particles affixed.

In some embodiments, the trapping region is relatively thin but may be quite wide to provide relatively high throughput. In other words, the cross-sectional area of the channel itself is relatively large while the height or depth of the channel is quite thin. The thinness of the channel may be defined by the effective reach of the magnetic field which is used to attract the magnetic particles flowing through the trapping region in the fluid medium.

Various details of fluidics systems suitable for use with this invention are discussed in other contexts in the description of flow modules in U.S. patent application Ser. No. 11/583,989 filed Oct. 18, 2006, which is incorporated herein by reference for all purposes. Examples of such details include buffer composition, magnetic particle features, external magnet features, ferromagnetic materials for MFGs, flow conditions, sample types, integration with other modules, control systems for fluidics and magnetic elements, binding mechanisms between target species and magnetic particles, etc. Generally, in a magnetic trapping module the applied external magnetic field will be relatively higher (considering the overall design of the module) than that employed in a continuous flow magnetic flow sorter of the type described in U.S. patent application Ser. No. 11/583,989. In any event, the magnetic force exerted on target species should be sufficiently greater than the hydrodynamic drag force in order to ensure that the target species (coupled to magnetic particles) are captured and held in place against the flowing fluid.

In a typical example, the magnetic trapping process proceeds as follows. First, a sample such as a biological specimen potentially containing the target cells are labeled with small magnetic particles coated with a capture moiety (e.g., an antibody) specific for the surface marker of the target cell. This labeling process may take place on or off the microfluidic sorting device. After this labeling, the sample is flowed into the sorting station (comprising a trapping region) with or without concurrently flowing buffer solution. Buffer may be delivered through one or more inlets and sample through one or more others. The sorting station is energized with an external magnetic field to hold the magnetically labeled target cells or other species in place against the hydrodynamic drag force exerted by the flowing fluid. This occurs while continuously eluting the un-labeled non-target species. As explained above, the magnetic field is typically applied by an external magnet positioned proximate the sorting station. After most, or all, of the sample solution has flowed clear of the sorting station, the magnetic components may be released by any of a number of different mechanisms including some that involve modifying the magnetic field gradient and/or increasing the hydrodynamic force. For example, the magnetic field in the chamber may be reduced, removed, or reoriented and concurrently the sample inlet flow is replaced with release agent (for releasing the captured species) and/or buffer flow. Ultimately the previously immobilized magnetic components, or just their captured species (now purified), flow out of the chamber in a buffer solution. The purified sample component comprising the target species may then be collected at an outlet of the sorting chamber, which, in some configurations may be located directly downstream from the trapping chamber.

A capture and release protocol is particularly advantageous when using large target species such as mammalian cells that respond strongly to hydrodynamic forces and relatively weakly to magnetic forces (possibly because only one or a small number of magnetic particles attached to the cell are influenced by the magnetic field gradient generators). The capture and release protocol may also be beneficial when using relatively small target species such as viruses which have a tendency to become entrained in a boundary layer of a flow field within a microfluidic device.

There are various advantages of using trapping type sorting modules. Among these are the following.

1. The target species can be greatly concentrated because only a small elution volume is used to release the trapped target species. Over time, target species from a low concentration sample are extracted and held fixed until the entire sample is processed. Then the captured species are released in a relatively small volume of carrier medium, thereby producing a high purity, high concentration solution or suspension.

2. The physical dimensions of the sorter can be relatively large because it may employ relatively large magnetic fields, influencing magnetic particles over relatively large distances in a sorting module. As an example, the flow channel height may be 20 micrometers or larger. This allows for relatively high throughput (e.g., at least about 10 ml/hour, or 50 ml/hour, or 100 ml/hour, or 1 litre/hour).

3. A monolayer (or sub-monolayer) of captured species can be produced. Alternatively, a layer consisting of only a few sub-layers (e.g., a bilayer or trilayer) can be produced. In either case, large “clumps” which might constrict the flow passage or otherwise interfered with trapping can be avoided. This is possible because the external field can be dynamically controlled as described below. Alternatively, or in addition, MFGs can be employed to limit application of very strong magnetic forces on magnetic particles over only small distances. Limiting captured species to a monolayer has various advantages. One of these is in providing an unobstructed flow path above the monolayer. Hence it is unlikely that non-target species will become entrained in a mass of target species while flowing through the trapping module. Another advantage resides in the ability to image distinct species of monolayer at a well defined depth of focus.

4. An array of external magnets may be employed (see e.g., FIG. 1B). This allows fine tuning of the magnetic field over the domain of the sorting module. In some embodiments, the array of magnets employs alternating polarity magnets as shown in FIG. 1B, although this is not necessary. In some embodiments, only two magnets are employed (both disposed below the MFGs).

5. The dimensions and shape of the flow channel in the sorting module can be varied over the flow path in order to control hydrodynamic forces acting on the magnetic particles (and associated target species). In this way, the balance of magnetophoretic and hydrodynamic forces can be tailored to yield a high performance separation.

It should be understood that embodiments of the invention are not limited to analysis of biological or even organic materials, but extend to non-biological and inorganic materials. Thus, the apparatus and methods described above can be used to screen, analyze or otherwise process a wide range of biological and non-biological substances in liquids. The target and/or non-target species may comprise small or large chemical entities of natural or synthetic origin such as chemical compounds, supermolecular assemblies, organelles, fragments, glasses, ceramics, etc. In certain embodiments, they are monomers, oligomers, and/or polymers having any degree of branching. They may be expressed on a cell or virus or they may be independent entities. They may also be complete cells or viruses themselves.

The magnetic capture particles employed in separations of this invention may take many different forms. In certain embodiments, they are superparamagnetic particles or nanoparticles, although in some cases they may be ferromagnetic or paramagnetic. As a general proposition, the magnetic particles should be chosen to have a size, mass, and susceptibility that allow them to be easily diverted from the direction of fluid flow when exposed to a magnetic field in microfluidic device (balancing hydrodynamic and magnetic effects). In certain embodiments, the particles do not retain magnetism when the field is removed. In a typical example, the magnetic particles comprise iron oxide (Fe₂O₃ and/or Fe₃O₄) with diameters ranging from about 10 nanometers to about 100 micrometers. However, embodiments are contemplated in which even larger magnetic particles are used.

The magnetic particles may be coated with a material rendering them compatible with the fluidics environment and allowing coupling to particular target components. Examples of coatings include polymer shells, glasses, ceramics, gels, etc. In certain embodiments, the coatings are themselves coated with a material that facilitates coupling or physical association with targets. For example, a polymer coating on a micromagnetic particle may be coated with an antibody, nucleic acid sequence, avidin, or biotin.

One class of magnetic particles is the nanoparticles such as those available from Miltenyi Biotec Corporation of Bergisch Gladbach, Germany. These are relatively small particles made from coated single-domain iron oxide particles, typically in the range of about 10 to 100 nanometers diameter. They are coupled to specific antibodies, nucleic acids, proteins, etc. Magnetic particles of another type are made from magnetic nanoparticles embedded in a polymer matrix such as polystyrene. These are typically smooth and generally spherical having diameters of about 1 to 5 micrometers. Suitable beads are available from Invitrogen Corporation, Carlsbad, Calif. These beads are also coupled to specific antibodies, nucleic acids, proteins, etc.

Dynamically Varying External Magnetic Fields

In accordance with embodiments of this invention, a dynamically varying magnetic field is applied to the trapping region during flow of the magnetic particles. This may involve, for example, progressive insertion of a magnetic field over the trapping region during the trapping operation.

This approach has the advantage of reducing or preventing build up of magnetic particles at the leading edge or elsewhere in the trapping region. Generally, a build up has been observed to occur where the magnetic field is strongest, typically at the edge of a permanent magnet used to apply the external magnetic field. As should be clear, such build up can result in under utilization of the trapping region (portions of the trapping region where the magnetic field strength is not great might not capture many or any of the magnetic particles). Further, the clump or pile up of magnetic particles may actually block passage of further magnetic particles to the down stream portions of the trapping region. It may also capture unbound species from the sample and thereby reduce purity of the captured components of the sample.

By using a dynamically varying magnetic field in accordance with this invention, one can produce a relatively evenly dispersed layer of the magnetic particles captured over the trapping region. In some cases, this layer is effectively a monolayer of magnetic particles on the trapping region, although sub-monolayers, as well as bilayers, and the like may be produced depending upon the area of the trapping region and the quantity of sample to be processed.

A relatively uniform distribution of magnetic particles in the trapping region may be useful during post-separation operations such as bead release. The release agent will fill the entire the channel and the uniform spreading of magnetic bound target particles will allow greater access to the magnetic bead bound target particles by the release agent.

The external magnet (or a system of magnets) that is variably positioned during capture of the magnetic particles may be driven by any of a number of different means, some of which will be described below. Further, the external magnet may be a permanent magnet or electromagnet, or multiples of either of these or combinations of permanent and electromagnets.

In accordance with some embodiments of this invention, the position of greatest magnetic field strength is gradually moved over the trapping region during the period of time when particles are flowing into the channel. The direction of movement of the magnetic field during trapping may be, in one embodiment, from a down stream position to an up stream position within the trapping region. In other words, the direction of movement of the magnetic field is opposite that of the direction of the fluid flow in the trapping region. Such embodiments may involve, for example, moving a permanent magnet in a direction from a downstream position to an upstream position underneath the base of a flow channel, particularly the region of the channel comprising the trapping region. Thus, as magnetic particles first enter the trapping region, the leading edge of the permanent magnet is positioned just beyond the downstream edge of the trapping region. Thereafter, as the magnetic particles begin to flow into the trapping region, the leading edge of the permanent magnet is gradually moved upstream and ultimately comes to rest at or near the upstream boundary of the trapping region. In certain embodiments, it reaches its position at about the time when the magnetic particles cease flowing into the trapping region.

In an alternative embodiment, the external magnet moves from the upstream to the downstream positions of the trapping region during capture of the magnetic particles. In other words, the external magnet moves in the same direction as the fluid flow. In this embodiment, as in the previously described embodiment, the duration of the movement of the external magnet should correspond, at least roughly, to the period of time during which magnetic particles are flowing through the trapping region. As explained below with reference to FIG. 2C, one specific embodiment employs a downstream movement of a magnet to sequentially capture and release and capture and release . . . the same particles in order to remove non-specifically bound sample species from the magnetic particles.

As indicated, control of the repositioning of the magnetic field within the trapping region can be accomplished by various mechanisms. In a first embodiment, this is accomplished by moving a magnetic field producer (e.g., a permanent magnet) over one surface of the trapping region (typically outside the channel) during the passage of magnetic particles through the trapping region. FIG. 2A depicts an example of this embodiment. As shown, a permanent magnet 203 moves under a trapping region 201 during capture of magnetic particles. In the depicted embodiment, magnet 203 moves from a downstream position 205 toward an upstream position 207 during the trapping operation. It produces a magnetic field interaction volume 209 that effectively spans the height of a trapping region fluidic volume. Thus, all magnetic particles in the fluid flowing through the trapping region volume experience the force produced by the moving magnetic field producer 203.

In another embodiment, the external magnet is an electromagnet which moves along the trapping region (same as the permanent magnet) during the flow of magnetic particles into the trapping region. Optionally, the position of the magnetic field produced by the electromagnet can be controlled by other means such as mechanically moving some or all of the electromagnet's coils during the trapping period.

In another embodiment, the dynamic repositioning of the magnetic field during trapping is accomplished by sequential insertion of a series of external magnets, each of relatively small size with respect of the size of the trapping region. In one embodiment, the magnets are permanent magnets. In a specific embodiment, these permanent magnets are arranged in alternating polarities (e.g., a first magnet has its south pole oriented toward the trapping region, a second magnet has its north pole oriented toward the trapping region, a third magnet has its south pole oriented toward the trapping region, a fourth magnet has its north pole oriented toward the trapping region, etc.). FIG. 1C shows an example of such arrangement of permanent magnets.

Typically, in embodiments involving sequential insertion of the plurality of magnets, the magnets are arranged along the axial flow direction. In one example, the number of magnets is about 5 to 50. In a specific embodiment, about 20 separate permanent magnets are employed and arranged in alternating polarities, each having a width (dimension along the axial flow direction) of approximately 0.5 to 10 millimeters (e.g., 1.5 millimeters). More generally, the width of the individual permanent magnets is determined, at least in part, by the axial length of the trapping region and the number of magnets to be inserted.

In a typical embodiment, the first inserted magnet is the most downstream magnet and then progressively the upstream magnets are inserted during the course of the introduction of magnetic particles into the trapping chamber. In an alternative embodiment, the sequence of insertion can be reversed such that the first inserted magnet is the leading upstream position magnet, the second inserted magnet is the next successive downstream positioned magnet, etc.

In one embodiment, a cam actuator is used to progressively insert a plurality of magnets under a fluid channel (the trapping region). FIG. 2B presents an example of such actuator. In this example, a cam actuator 231 includes five separate cams (233, 235, 237, 239, and 241) associated with five separate magnets (243, 245, 247, 249, and 251), each associated with a different position in a trapping region 253. As the cam actuator 231 rotates in the direction shown, a cam lobe in cam 233 engages a push member 255 connected to a first magnet 243. As actuator 231 continues to rotate, cam 233 pushes magnet 243 into position under a downstream portion of trapping region 253. However, the other cams, which are angularly offset from cam 233, have not yet engaged their respective magnets and as a consequence only magnet 243 is in position to influence trapping region 253. See FIG. 2C. Thereafter, as cam actuator 231 continues to rotate in the direction shown, cams 235, 237, 239, and 241 sequentially engage associated push members and drive their respective magnets 245, 247, 249, and 251 into position under trapping region 253. See FIGS. 2D and 2E. As a consequence, trapping region 253 is gradually exposed to an external magnetic field, starting at a downstream position and successively moving upstream until the entire trapping region is exposed to the magnetic field.

Those of skill in the relevant art will understand that there are numerous other actuating mechanisms that could be used to mechanically, electrically, and/or electromechanically position magnets within the domain of a trapping region during fluid flow. Examples include solenoid drivers, electrical motors, pneumatic drives, hydraulic drivers, and the like.

The timing of the insertion of the external magnet(s) into the trapping region, in typically embodiments, corresponds at least roughly to the time period during which magnetic particles flow through the trapping region. In other words, the movement of the external magnet with respect to the trapping region may begin at about the same time that magnetic particles are introduced to the trapping region and end at about the same time when the last magnetic particles leave the trapping region. It may be useful to characterize this duration (the total time in which the magnetic particle bearing solution flows through the trapping region) as a “separation period.” Thus, in some embodiments, this period corresponds, at least roughly, to the period of time during which the external magnetic field is dynamically varied in the trapping region (e.g., the time during which external magnets are moved with respect to the trapping region). In other cases, however, the magnetic field will be fully developed in the trapping region for some time prior to the end of the separation period. In either case, the movement of the external magnetic field with respect to the trapping region may be smooth and continuous or stepped and discontinuous, as appropriate for the particular application.

Typically, the magnetic field when fully applied to the trapping region at the end of the separation period may be maintained for a further period of time to retain the magnetic particles in the trapping region for subsequent processing such as washing, release of captured target agent, etc.

FIG. 2F depicts one example of a staged trapping system. As shown, magnetically labeled target species 271 and non-target species 273 are first flowed over a leftmost trapping region 275 of a fluidic channel 285 comprising a “soft” magnetic pattern (array of ferromagnetic structures) 277, which traps the magnetically-tagged target species as well as non-specifically trapping a few non-target species. The non-specific trapping may be caused by factors such as physical entrapment by the target species. An external magnet 279 (which may be a collection of magnets in some embodiments) is positioned proximate trapping region 275 during this initial trapping operation. Thereafter, external magnet 279 is moved downstream to the second trapping stage 281, allowing the trapped species to be released from the leftmost trapping stage 275. The magnetically-tagged species are trapped again in the second stage 281, and more of the non-target species are flushed out of the channel as fluid continues to flow through the stages which are aligned along a single channel. In a third trapping stage 283, the last of the non-target species are flushed out of the channel, leaving only the magnetically-tagged target species on a pattern 287. External magnet 279 can now be removed to elute the target species if so desired. An advantage of using this staged system of magnetic trapping, release, and re-trapping (as opposed to a single trapping stage) is that any non-specifically bound non-target species such as cells will be more effectively removed from the magnetic traps between the consecutive trapping stages, thus enhancing the purity of the eluted target cells or other species.

Processing Trapped Species

In some embodiments, trapped species will be released from their associated magnetic particles in while confined to a trapping region. As mentioned, various mechanisms may be employed for this purpose. One approach involves applying a bead release agent to the trapped magnetic particles. Such agents may act by cleaving a chemical linker between the beads and the captured species or by competitively binding a linking species. Of course, other cleaving or release agents may be employed as will be understood by those of skill in the art.

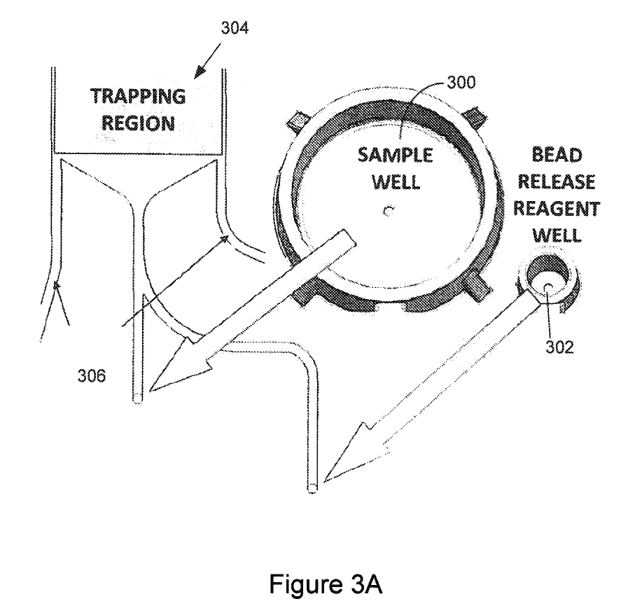

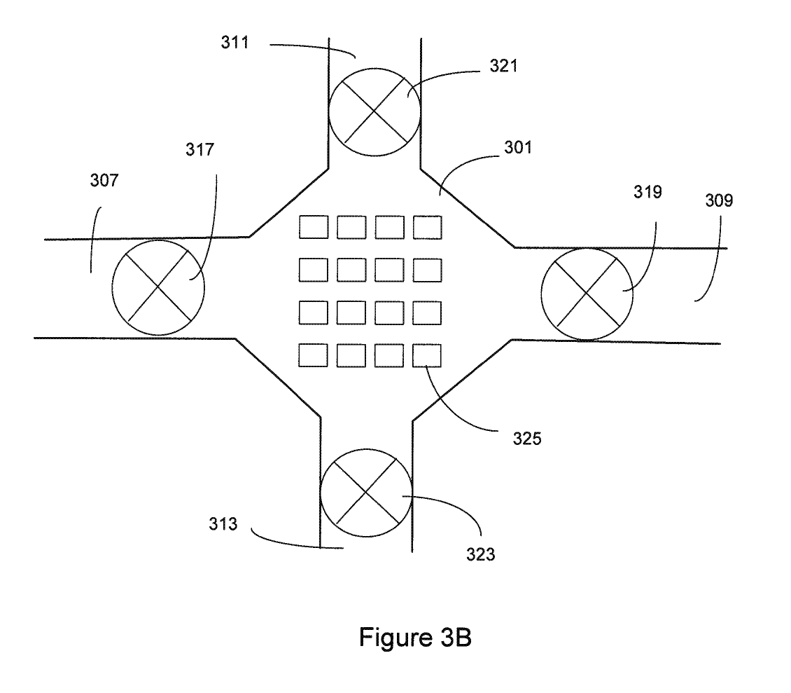

FIG. 3A depicts a fluidics input for a sample well 300 and a bead release reagent well 302. During a separation process, sample is pumped from sample well 300 into a trapping region 304. Once separation process is complete, bead release reagent is pumped from the release reagent well 302 into the trapping region 304. To elute the release cells, buffer can be pumped in from either of the input wells, or from wall buffer inlets 306. The pumping action in all cases can be achieved using, e.g., either a gas (such as air) or liquid (such as buffered water).

Trapped target species may be simply concentrated, purified and/or released as described. Alternatively they can be further analyzed and/or treated. FIG. 3B shows the structure of a magnetic trap 301 disposed in a fluidics device 305 for post-capture treatment of captured species. As shown, trap 301 includes an inlet line 307 for receiving a raw sample stream and an outlet line 309. Trap 301 also includes auxiliary lines 311 and 313 for providing one or more other reagents. Each of lines 307, 309, 311, and 313 includes its own valve 317, 319, 321, and 323, respectively. Within trap 301 are various trapping elements 325. These may be ferromagnetic elements that shape or deliver a magnetic field, etc.

While a magnetic field or other capturing stimulus is applied to the trap features 325, the particles flowing into trap 301 are captured. After a sufficient number of particles are captured (which might be indicated by simply running a sample stream through device 305 for a defined period of time), valves 317 and 319 are closed. Thereafter, in one embodiment, valves 321 and 323 are opened, and a buffer is passed from line 311, through trap 301, and out line 313. This serves to wash the captured particles. After washing for a sufficient length of time, the washed particles may be recovered by eluting (by e.g., removing an external magnetic or electrical field while the buffer continues to flow), by pipetting from trap 301, by removing a lid or cover on the trap or the entire device, etc. Regarding the last option, note that in some embodiments the devices are disposable and can be designed so that the top portion or a cover is easily removed by, e.g., peeling.

In another embodiment, the particles that have been captured and washed in the trap as described above are exposed to one or more markers (e.g., labeled antibodies) for target cells or other target species in the sample. Certain tumor cells to be detected, for example, express two or more specific surface antigens. This combination of antigens occurs only in very unique tumors. To detect the presence of such cells bound to magnetic particles, valves 317 and 323 may be closed and valve 321 opened after capture in trap 301 is complete. Then a first label is flowed into trap 301 via line 311 and out via line 309. Some of the label may bind to immobilized cells in trap 301. Thereafter, valve 321 is closed and valve 323 is opened and a second label enters trap 301 via line 313. After label flows through the trap for a sufficient length of time, the captured particles/cells may be washed as described above. Thereafter, the particles/cells can be removed from trap 301 for further analysis or they may be analyzed in situ. For example, the contents of trap 301 may be scanned with probe beams at excitation for the first and second labels if such labels or fluorophores for example. Emitted light is then detected at frequencies characteristic of the first and second labels. In certain embodiments, individual cells or particles are imaged to characterize the contents of trap 301 and thereby determine the presence (or quantity) of the target tumor cells. Of course various target components other than tumor cells may be detected. Examples include pathogens such as certain bacteria or viruses.

In another embodiment, nucleic acid from a sample enters trap 301 via line 307 and is captured by an appropriate mechanism (examples set forth below). Subsequently, valve 317 is closed and PCR reagents (nucleotides, polymerase, and primers in appropriate buffers) enter trap 101 via lines 311 and 313. Thereafter all valves (317, 319, 321, and 323) are closed and an appropriate PCR thermal cycling program is performed on trap 301. The thermal cycling continues until an appropriate level of amplification is achieved. Subsequently in situ detection of amplified target nucleic acid can be performed for, e.g., genotyping. Alternatively, the detection can be accomplished downstream of trap 301 in, e.g., a separate chamber which might contain a nucleic acid microarray or an electrophoresis medium. In another embodiment, real time PCR can be conducted in trap 301 by introducing, e.g., an appropriately labeled intercalation probe or donor-quencher probe for the target sequence. The probe could be introduced with the other PCR reagents (primers, polymerase, and nucleotides for example) via line 311 or 313. In situ real time PCR is appropriate for analyses in which expression levels are being analyzed. In either real time PCR or end point PCR, detection of amplified sequences can, in some embodiments, be performed in trap 301 by using appropriate detection apparatus such as a fluorescent microscope focused on regions of the trap.

For amplification reactions, the capture elements 325 capture and confine the nucleic acid sample to reaction chamber 301. Thereafter, the flow through line 307 is shut off and a lysing agent (e.g., a salt or detergent) is delivered to chamber 301 via, e.g., line 311 or 313. The lysing agent may be delivered in a plug of solution and allowed to diffuse throughout chamber 101, where it lyses the immobilized cells in due course. This allows the cellular genetic material to be extracted for subsequent amplification. In certain embodiments, the lysing agent may be delivered together with PCR reagents so that after a sufficient period of time has elapsed to allow the lying agent to lyse the cells and remove the nucleic acid, a thermal cycling program can be initiated and the target nucleic acid detected.

In other embodiments, sample nucleic acid is provided in a raw sample and coupled to magnetic particles containing appropriate hybridization sequences. The magnetic particles are then sorted and immobilized in trap 301. After PCR reagents are delivered to chamber 301 and all valves are closed, PCR can proceed via thermal cycling. During the initial temperature excursion, the captured sample nucleic acid is released from the magnetic particles.

The nucleic acid amplification technique described here is a polymerase chain reaction (PCR). However, in certain embodiments, non-PCR amplification techniques may be employed such as various isothermal nucleic acid amplification techniques; e.g., real-time strand displacement amplification (SDA), rolling-circle amplification (RCA) and multiple-displacement amplification (MDA). Each of these can be performed in a trap such as chamber 301 shown in FIG. 3B.

Example Magnetic Trapping Structures

Most fundamentally, a trapping station is defined by the boundaries of a region or channel in a fluidics device. Fluid flows through the trapping station and encounters a magnetic field generated by one or more external magnets proximate the trapping station. In addition, a trapping station may optionally employ a magnetic field gradient generator (MFGs). MFG elements (e.g., strips, pins, dots, grids, random arrangements, etc.) shape the external magnet field to produce a locally high magnetic field gradient in the trapping station.

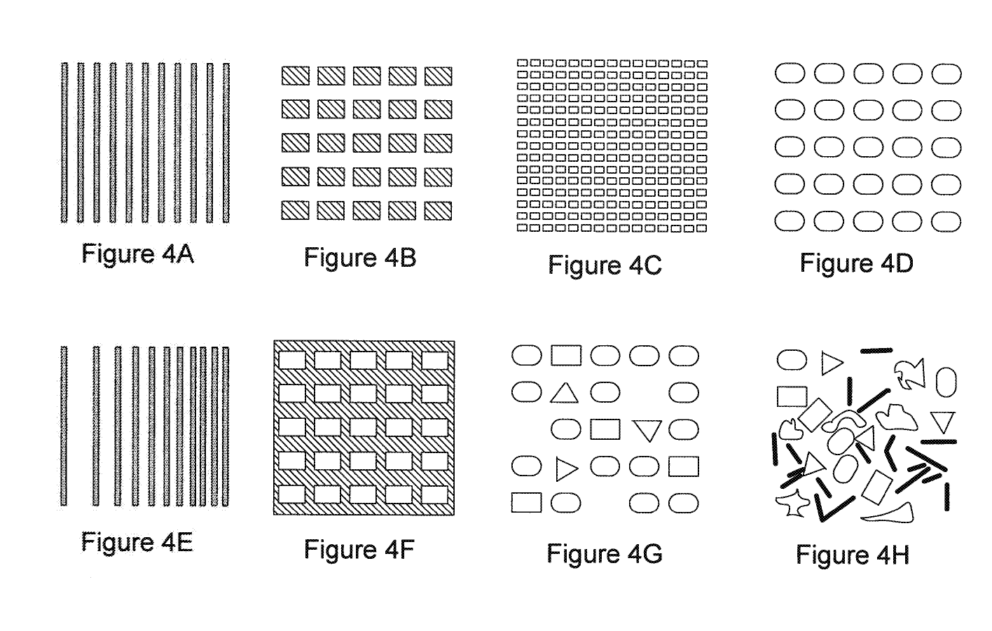

FIG. 4A-4H depicts examples of different types of ferromagnetic MFG structures that may be employed with magnetic trapping stations this invention. Eight different ferromagnetic element patterns are shown in the figure. These are employed to shape a magnetic field gradient originating from an external source of a magnetic field (not shown). As shown, the ferromagnetic structures are provided in an organized pattern, such as parallel lines, an orthogonal grid, and rectangular arrays of regular or irregular geometric shapes. The structures may be regular or reticulated as shown. Other embodiments, not shown, may employ parallel stripes, etc.

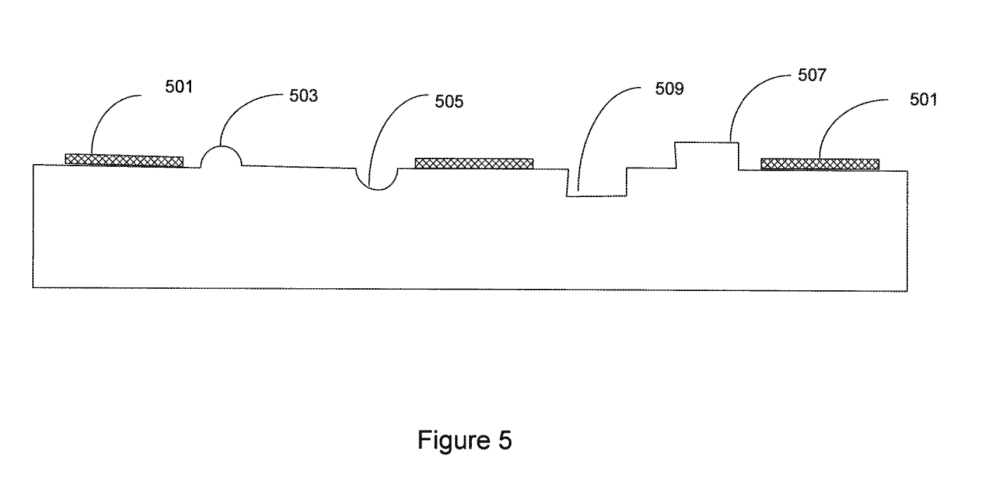

Generally, the features or elements in these patterns may be made from various materials having permeabilities that are significantly different from that of the fluid medium in the device (e.g., the buffer). As indicated, the elements may be made from a ferromagnetic material. In a specific embodiment, the patterns are defined by nickel features on a glass or polymer substrate. In alternative embodiments, the MFG structures are combined with other types of capture structures such as electrodes, specific binding moieties (e.g., regions of nucleotide probes or antibodies), physical protrusions or indentations, etc. FIG. 5 presents examples of non-magnetic capture features that are fabricated among a soft-magnetic (e.g., nickel) pattern. The patterns may be positive (503 and 507) or negative (505 and 509) surface features to facilitate laminar mixing of the fluid over the nickel structures (501), causing enhanced magnetic trapping.

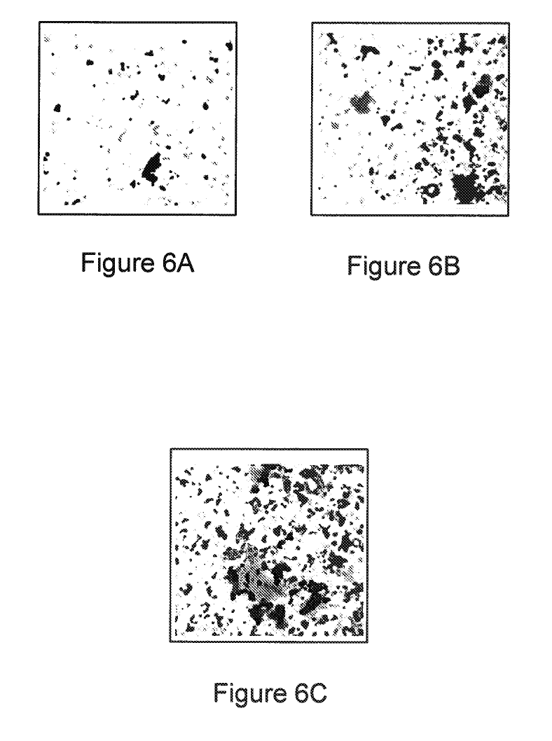

Other types of MFG structures comprise ferromagnetic materials that do not form well-defined shapes or regular features. Instead, the structures form randomly placed features such as randomly dispersed powder, filings, granules, etc. These structures are affixed to one or more walls of the trapping station adhesives, pressure bonding, etc. FIG. 6 shows examples of random array of ferromagnetic structures from left to right: 5%, 10% and 30% nickel powder in an epoxy resin. Such structures have found to be effective MFG elements in magnetic trapping stations.

In an alternative embodiment, the trapping station contains no MFG structures. Instead, magnetic capture is based solely on the strength of the external magnetic field, without the aid of a field shaping element such as MFG structures.

Fluidics and Sorting Chamber Design

While some embodiments of this invention are implemented in micro-scale microfluidic systems, it should be understood that methods, apparatus, and systems of this invention are not limited to microfluidic systems. Typical sizes of larger trapping chambers range between about 1 and 100 millimeters in length (in the direction of flow), between about 1 and 100 millimeters in width and between about 1 micrometer and 10 millimeters depth (although typically about 1 millimeter or less). The depth and width together define the cross section through which fluid flows. The depth represents the dimension in the direction that the magnetic field penetrates into the channel, typically a direction pointed away from the position of the external magnet. In certain embodiments, the chambers have an aspect ratio (length to width) that is greater than 1, e.g., about 2 to 8.

In general, the applied magnetic field should be sufficiently great to capture or trap magnetic particles flowing in a fluid medium. Those of skill in the art will recognize that the applied magnetic force must be significantly greater than the hydrodynamic force exerted on the particles by the flowing fluid. This may limit the depth dimension of the trapping station.

In certain embodiments, the integrated fluidics systems are microfluidic systems. Microfluidic systems may be characterized by devices that have at least one “micro” channel. Such channels may have at least one cross-sectional dimension on the order of a millimeter or smaller (e.g., less than or equal to about 1 millimeter). Obviously for certain applications, this dimension may be adjusted; in some embodiments the at least one cross-sectional dimension is about 500 micrometers or less. In some embodiments, as applications permit, a cross-sectional dimension is about 100 micrometers or less (or even about 10 micrometers or less—sometimes even about 1 micrometer or less). A cross-sectional dimension is one that is generally perpendicular to the direction of centerline flow, although it should be understood that when encountering flow through elbows or other features that tend to change flow direction, the cross-sectional dimension in play need not be strictly perpendicular to flow. Often a micro-channel will have two or more cross-sectional dimensions such as the height and width of a rectangular cross-section or the major and minor axes of an elliptical cross-section. Either of these dimensions may be compared against sizes presented here. Note that micro-channels employed in this invention may have two dimensions that are grossly disproportionate—e.g., a rectangular cross-section having a height of about 100-200 micrometers and a width on the order or a centimeter or more. Of course, certain devices may employ channels in which the two or more axes are very similar or even identical in size (e.g., channels having a square or circular cross-section).

Often a controller will be employed to coordinate the operations of the various systems or sub-systems employed in the overall microfluidic system. Such controller will be designed or configured to direct the sample through a microfluidic flow passage. It may also control other features and actions of the system such as the strength and orientation of a magnetic field applied to fluid flowing through the microfluidic device, control of fluid flow conditions within the microfluidic device by actuating valves and other flow control mechanisms, mixing of magnetic particles and sample components in an attachment system, generating the sample (e.g., a library in a library generation system), and directing fluids from one system or device to another. The controller may include one or more processors and operate under the control of software and/or hardware instructions.

Integration

Examples of operational modules that may be integrated with magnetic trapping sorters in fluidics devices include (a) additional enrichment modules such as fluorescence activated cell sorters and washing modules, (b) reaction modules such as sample amplification (e.g., PCR) modules, restriction enzyme reaction modules, nucleic acid sequencing modules, target labeling modules, chromatin immunoprecipitation modules, crosslinking modules, and even cell culture modules, (c) detection modules such as microarrays of nucleic acids, antibodies or other highly specific binding agents, and fluorescent molecular recognition modules, and (d) lysis modules for lysing cells, disrupting viral protein coats, or otherwise releasing components of small living systems. Each of these modules may be provided before or after the magnetic sorter. There may be multiple identical or different types of operational modules integrated with a magnetic sorter in a single fluidics system. Further, one or more magnetic sorters may be arranged in parallel or series with respect to various other operational modules. Some of these operational modules may be designed or configured as traps in which target species in a sample are held stationary or generally constrained in particular volume.

As should be apparent from the above examples of modules, operations that may be performed on target and/or non-target species in modules of integrated fluidics devices include sorting, coupling to magnetic particles (sometimes referred to herein as “labeling”), binding, washing, trapping, amplifying, removing unwanted species, precipitating, cleaving, diluting, ligating, sequencing, synthesis, labeling (e.g., staining cells), cross-linking, culturing, detecting, imaging, quantifying, lysing, etc.

Specific examples of biochemical operations that may be performed in the magnetic sorting modules of integrated fluidic devices include synthesis and/or screening of plasmids, aptamers, proteins, and peptides; evaluating enzyme activity; and derivatizing proteins and carbohydrates. A broad spectrum of biochemical and electrophysiological assays may also be performed, including: (1) genomic analysis (sequencing, hybridization), PCR and/or other detection and amplification schemes for DNA, and RNA oligomers; (2) gene expression; (3) enzymatic activity assays; (4) receptor binding assays; and (5) ELISA assays. The foregoing assays may be performed in a variety of formats, such as: homogeneous, bead-based, and surface bound formats. Furthermore, devices as described herein may be utilized to perform continuous production of biomolecules using specified enzymes or catalysts, and production and delivery of biomolecules or molecules active in biological systems such as a therapeutic agents. Microfluidic devices as described herein may also be used to perform combinatorial syntheses of peptides, proteins, and DNA and RNA oligomers as currently performed in macrofluidic volumes.

Examples of Reactors and Lysis Modules in Fluidics Systems

Various features may be employed in a microfluidic reactor employed in an integrated device of this invention. The exact design and configuration will depend on the type of reaction: thermal management system, micromixers, catalyst structures and a sensing system. In certain embodiments, a thermal management system includes heaters, temperature sensors and heat transfer (micro heat exchanges). In microreactors, all components can be integrated in resulting in a very precise control of temperatures which is crucial for instance in PCR for DNA amplification.

Micromixers may be used for mixing two solutions (e.g. a sample and a reagent) to make the reaction possible. In microscale systems, mixing often relies on diffusion due to the laminar behavior of fluid at low Reynolds numbers. In one embodiment, a hydrophobic material defining a hole separates two adjacent chambers. When aqueous solutions are used, the hydrophobicity of the interface permits both chambers to be filled with fluid plugs without mixing. A pressure gradient can then be applied to force fluid through the hole in the hydrophobic layer to induce diffusion between the two plugs. In one embodiment, the hole is actually a slit in which no material is removed from the intermediate dividing layer.

Catalyst structures may be employed to accelerate a chemical reaction (e.g., cross-linking or sequencing). In microreactors, the catalyst can be implemented in the form of, e.g., fixed beads, wires, thin films or a porous surface. While beads and wires and not compatible with batch fabrication, thin films and porous surface catalysts can be integrated in the fabrication of microreactors.

A sensing system may employ chemical microsensors or biosensors, for example. Designing a microreactor with glass or plastic provides optical access to the reaction chamber and thus, all optical measurement methods.

Before the contents of a biological cell may be analyzed, the cells to be analyzed are made to burst so that the components of the cell can be separated. The methods of cell disruption used to release the biological molecules in a cell and in a virus include, e.g., electric field, enzyme, sonication, and using a detergent. Mechanical forces may also be used to shear and burst cell walls.

The cell lysis may be performed by subjecting the cells trapped in a reaction chamber to pulses of high electric field strength, typically in the range of about 1 kV/cm to 10 kV/cm. The use of enzymatic methods to remove cell walls is well-established for preparing cells for disruption, or for preparation of protoplasts (cells without cell walls) for other uses such as introducing cloned DNA or subcellular organelle isolation. The enzymes are generally commercially available and, in most cases, were originally isolated from biological sources (e.g. snail gut for yeast or lysozyme from hen egg white). The enzymes commonly used include lysozyme, lysostaphin, zymolase, cellulase, mutanolysin, glycanases, proteases, mannase etc.

In addition to potential problems with the enzyme stability, the susceptibility of the cells to the enzyme can be dependent on the state of the cells. For example, yeast cells grown to maximum density (stationary phase) possess cell walls that are notoriously difficult to remove whereas midlog growth phase cells are much more susceptible to enzymatic removal of the cell wall. If an enzyme is used, it may have to be sorted and removed from the desired material before further analysis.

Sonication uses a high-frequency wave that mechanically burse the cell walls. Ultrasound at typically 20-50 kHz is applied to the sample via a metal probe that oscillates with high frequency. The probe is placed into the cell-containing sample and the high-frequency oscillation causes a localized high pressure region resulting in cavitation and impaction, ultimately breaking open the cells. Cell disruption is available in smaller samples (including multiple samples under 200 μL in microplate wells) and with an increased ability to control ultrasonication parameters.

Detergent-based cell lysis is an alternative to physical disruption of cell membranes, although it is sometimes used in conjunction with homogenization and mechanical grinding. Detergents disrupt the lipid barrier surrounding cells by disrupting lipid:lipid, lipid:protein and protein:protein interactions. The ideal detergent for cell lysis depends on cell type and source and on the downstream applications following cell lysis. Animal cells, bacteria and yeast all have differing requirements for optimal lysis due to the presence or absence of a cell wall. Because of the dense and complex nature of animal tissues, they require both detergent and mechanical lysis to effectively lyse cells.

In general, nonionic and zwitterionic detergents are milder, resulting in less protein denaturation upon cell lysis, than ionic detergents and are used to disrupt cells when it is critical to maintain protein function or interactions. CHAPS, a zwitterionic detergent, and the Triton X series of nonionic detergents are commonly used for these purposes. In contrast, ionic detergents are strong solubilizing agents and tend to denature proteins, thereby destroying protein activity and function. SDS, and ionic detergent that binds to and denatures proteins, is used extensively for studies assessing protein levels by gel electrophoresis and western blotting.

A mechanical method for cell disruption uses glass or ceramic beads and a high level of agitation to shear and burst cell walls. This process works for easily disrupted cells, is inexpensive, but has integration issues for the micrfluidic device. In one embodiment, beads are used in a closed chamber holding the sample and are agitated with an electric motor. In other embodiments, high pressure is applied to fluid containing the cell samples while forcing the fluid to flow through a very narrow channel. Shear between the cell and channel walls under such conditions would disrupt the cell.

Examples of Detectors in Integrated Flow Systems

In various applications envisaged for integrated microsystems it will be necessary to quantify the material present in a channel at one or more positions similar to conventional laboratory measurement processes. Techniques typically utilized for quantification include, but are not limited to, optical absorbance, refractive index changes, fluorescence emission, chemiluminescence, various forms of Raman spectroscopy, electrical conductometric measurements, impedance measurements (e.g., impedance cytometry) electrochemical amperiometric measurements, acoustic wave propagation measurements.

Optical absorbance measurements are commonly employed with conventional laboratory analysis systems because of the generality of the phenomenon in the UV portion of the electromagnetic spectrum. Optical absorbence is commonly determined by measuring the attenuation of impinging optical power as it passes through a known length of material to be quantified. Alternative approaches are possible with laser technology including photo acoustic and photo thermal techniques. Such measurements can be utilized with the integrated fluidics devices discussed here with the additional advantage of potentially integrating optical wave guides on microfabricated devices. The use of solid-state optical sources such as LEDs and diode lasers with and without frequency conversion elements would be attractive for reduction of system size.

Refractive index detectors have also been commonly used for quantification of flowing stream chemical analysis systems because of generality of the phenomenon but have typically been less sensitive than optical absorption. Laser based implementations of refractive index detection could provide adequate sensitivity in some situations and have advantages of simplicity. Fluorescence emission (or fluorescence detection) is an extremely sensitive detection technique and is commonly employed for the analysis of biological materials. This approach to detection has much relevance to miniature chemical analysis and synthesis devices because of the sensitivity of the technique and the small volumes that can be manipulated and analyzed (volumes in the picoliter range are feasible). For example, a 100 pL sample volume with 1 nM concentration of analyte would have only 60,000 analyte molecules to be processed and detected. There are several demonstrations in the literature of detecting a single molecule in solution by fluorescence detection. A laser source is often used as the excitation source for ultrasensitive measurements but conventional light sources such as rare gas discharge lamps and light emitting diodes (LEDs) are also used. The fluorescence emission can be detected by a photomultiplier tube, photodiode or other light sensor. An array detector such as a charge coupled device (CCD) detector can be used to image an analyte spatial distribution.

Raman spectroscopy can be used as a detection method for microfluidic devices with the advantage of gaining molecular vibrational information, but with the disadvantage of relatively poor sensitivity. Sensitivity has been increased through surface enhanced Raman spectroscopy (SERS) effects but only at the research level. Electrical or electrochemical detection approaches are also of particular interest for implementation on microfluidic devices due to the ease of integration onto a microfabricated structure and the potentially high sensitivity that can be attained. The most general approach to electrical quantification is a conductometric measurement, i.e., a measurement of the conductivity of an ionic sample. The presence of an ionized analyte can correspondingly increase the conductivity of a fluid and thus allow quantification. Amperiometric measurements imply the measurement of the current through an electrode at a given electrical potential due to the reduction or oxidation of a molecule at the electrode. Some selectivity can be obtained by controlling the potential of the electrode but it is minimal. Amperiometric detection is a less general technique than conductivity because not all molecules can be reduced or oxidized within the limited potentials that can be used with common solvents. Sensitivities in the 1 nM range have been demonstrated in small volumes (10 nL). The other advantage of this technique is that the number of electrons measured (through the current) is equal to the number of molecules present. The electrodes required for either of these detection methods can be included on a microfabricated device through a photolithographic patterning and metal deposition process. Electrodes could also be used to initiate a chemiluminescence detection process, i.e., an excited state molecule is generated via an oxidation-reduction process which then transfers its energy to an analyte molecule, subsequently emitting a photon that is detected.

Acoustic measurements can also be used for quantification of materials but have not been widely used to date. One method that has been used primarily for gas phase detection is the attenuation or phase shift of a surface acoustic wave (SAW). Adsorption of material to the surface of a substrate where a SAW is propagating affects the propagation characteristics and allows a concentration determination. Selective sorbents on the surface of the SAW device are often used. Similar techniques may be useful in the devices described herein.

The mixing capabilities of the microfluidic systems lend themselves to detection processes that include the addition of one or more reagents. Derivatization reactions are commonly used in biochemical assays. For example, amino acids, peptides and proteins are commonly labeled with dansylating reagents or o-phthaldialdehyde to produce fluorescent molecules that are easily detectable. Alternatively, an enzyme could by used as a labeling molecule and reagents, including substrate, could be added to provide an enzyme amplified detection scheme, i.e., the enzyme produces a detectable product. There are many examples where such an approach has been used in conventional laboratory procedures to enhance detection, either by absorbance or fluorescence. A third example of a detection method that could benefit from integrated mixing methods is chemiluminescence detection. In these types of detection scenarios, a reagent and a catalyst are mixed with an appropriate target molecule to produce an excited state molecule that emits a detectable photon.

### CONCLUSION

A number of embodiments of the invention have been described. Nevertheless, it will be understood that various modifications may be made without departing from the spirit and scope of the invention. For example, the above description has been focused on biological applications and in particular biological cell detection and trapping, but it should also be noted that the same principles apply to other particles, such as inorganic or non-biological organic materials. Thus, the apparatus and methods described above can also be used for non-biological substances in liquids. Accordingly, other embodiments are within the scope of the following claims.

What is claimed is:

1. A fluidic sorting device comprising:
(a) a fluidic chamber having (i) an inlet for receiving a sample in a fluid medium, (ii) an outlet for allowing the fluid medium to exit the fluidic chamber, and (iii) a surface for retaining magnetic particles captured by a magnetic field;
(b) an external source of the magnetic field in the fluidic chamber; and
(c) actuator means for moving the external source of the magnetic field with respect to the fluid chamber during trapping of the magnetic particles as they flow through the sorting device in the fluid medium.

2. The fluidic sorting device of claim 1, wherein the external source of the magnetic field comprises a single permanent magnet.

3. The fluidic sorting device of claim 1, wherein the external source of the magnetic field comprises a plurality of permanent magnets.

4. The fluidic sorting device of claim 1, wherein the external source of the magnetic field comprises an electromagnet.

5. The fluidic sorting device of claim 1, wherein the fluidic chamber further comprises a magnetic field gradient generator for exerting a magnetic force on a sample to capture, at least temporarily, magnetic particles in the fluid medium.

6. The fluidic sorting device of claim 5, wherein the magnetic field gradient generator comprises a ferromagnetic structure in an organized pattern.

7. The fluidic sorting device of claim 5, wherein the organized pattern is selected from the group consisting of parallel lines, an orthogonal grid, rectangular arrays of regular or irregular geometric shapes.

8. The fluidic sorting device of claim 5, wherein the magnetic field gradient generator comprises a random array of ferromagnetic structures.

9. The fluidic sorting device of claim 1, wherein the fluidic chamber does not contain any ferromagnetic structures.

10. The fluidic sorting device of claim 1, further comprising a pre-processing and/or a post-processing station integrated on the fluidic sorting device with the magnetic field gradient generator.

11. The fluidic sorting device of claim 10, wherein the pre-processing station comprises a labeling station for labeling target species in the sample with magnetic particles having an affinity for the target species.

12. The fluidic sorting device of claim 10, wherein the post-processing station comprises a detection station for detecting the target species.

13. The fluidic sorting device of claim 1, wherein the fluidic chamber has at least one sub-millimeter dimension.

14. The fluidic sorting device of claim 1, wherein the means for moving the external source of the magnetic field comprises a cam actuator.

15. The fluidic sorting device of claim 1, wherein the means for moving the external source of the magnetic field is configured to move the external source of the magnetic field from a downstream position toward an upstream position on the fluidic chamber.

16. The fluidic sorting device of claim 1, wherein the means for moving the external source of the magnetic field is configured to move the external source continuously as the magnetic particles flow through the sorting device in the fluid medium.

17. The fluidic sorting device of claim 1, wherein the external source of the magnetic field comprises a plurality of permanent magnets, and wherein the means for moving the external source of the magnetic field inserts the individual magnets of the plurality of magnets sequentially with respect to the surface for retaining magnetic particles.

18. A method for trapping magnetic particles in a trapping station of a fluidics device that includes (i) a fluidic chamber and (ii) an external source of the magnetic field in the fluidic chamber, the method comprising:
(a) flowing a sample into the fluid chamber, said sample comprising a plurality magnetic particles with molecular recognition elements thereon; and
(b) moving the external source of the magnetic field with respect to the fluid chamber while the magnetic particles flow through the sorting device in the fluid medium to thereby trap magnetic particles in a substantially uniform fashion on a surface of the fluidic chamber.
wherein moving the external source of the magnetic field with respect to the fluid chamber is performed with an actuator

19. The method of claim 18, wherein the actuator is a cam actuator.
